(19) United States
(12) Patent Application Publication
(10) Pub. No.: US 2024/0085891 A1
(43) Pub. Date: Mar. 14, 2024

(54) VIRTUAL METROLOGY METHODS FOR WAFERS, PREDICTION METHODS FOR CIRCUIT CHARACTERISTICS OF WAFERS AND PROCESS CONTROL SYSTEMS

(71) Applicant: Samsung Electronics Co., Ltd., Suwon-si (KR)

(72) Inventor: Jaehyun Choi, Suwon-si (KR)

(21) Appl. No.: 18/460,934

(22) Filed: Sep. 5, 2023

(30) Foreign Application Priority Data
Sep. 13, 2022 (KR) 10-2022-0114919

(51) Int. Cl. G05B 19/418

(52) U.S. Cl. CPC G05B 19/41875; G05B 2219/32368

(57) ABSTRACT

A virtual metrology method for a wafer includes collecting log data including process path information of wafers manufactured in a semiconductor process; collecting measured values of sample wafers of which physical characteristics are measured in the semiconductor process, the sample wafers being a group of wafers selected from among the manufactured wafers; classifying measured values of the sample wafers according to process paths based on the process path information; calculating a moving average value of measured values classified for each process path; and determining a moving average value corresponding to a process path of an unmeasured target wafer from among the manufactured wafers as a predicted value of the physical characteristics of the target wafer.

### CROSS TO REFERENCE TO RELATED APPLICATION

This application claims the benefit of priority to Korean Patent Application No. 10-2022-0114919 filed on Sep. 13, 2022, in the Korean Intellectual Property Office, and the entire contents of the above-identified application is incorporated by reference herein.

### BACKGROUND

Aspects of the present disclosure relate to virtual metrology methods for wafers, methods of predicting circuit characteristics of wafers, and process control systems.

A semiconductor process may consist of numerous unit processes. To reduce the wafer manufacturing time, sampling measurements may be performed on only a portion of manufactured wafers. Due to the sampling measurements only being performed on the portion of manufactured wafers, however, there may be a lack of measurement data, and as a result it may be difficult to predict wafer quality.

Recently, interest in virtual metrology (VM) has increased to address the issues of measurement-based process management. Virtual measurement may be used to predict measurement values for overall wafers without actually performing a measurement process by utilizing historical data of a device (e.g., a process device) used in the manufacturing process. When the measured value predicted through virtual measurement is interlocked with a process control system, product quality may improve and manufacturing costs and manufacturing time may be reduced. However, since the measured value of a wafer may be affected by numerous unit processes, it may be difficult to accurately predict the measured value only by using historical data related to a specific device.

### SUMMARY

Some example embodiments of the present disclosure provide virtual metrology methods which may enable measurement values predicted through virtual measurements of wafers to have high consistency with measured values.

Some example embodiments of the present disclosure provide methods of predicting circuit characteristics of semiconductor circuits formed on an unmeasured wafer, with the predicting having high accuracy.

Some example embodiments of the present disclosure provide process control systems which may control a process based on a virtual metrology method and a method of predicting circuit characteristics of a wafer.

According to some example embodiments of the present disclosure, a virtual metrology method for wafer may include collecting log data including process path information of wafers manufactured in a semiconductor process; collecting measured values of sample wafers of which physical characteristics are measured in the semiconductor process, the sample wafers being a group of wafers selected from among the manufactured wafers; classifying measured values of the sample wafers according to process paths based on the process path information; calculating a moving average value of measured values classified for each process path; and determining a moving average value corresponding to a process path of an unmeasured target wafer from among the manufactured wafers as a predicted value of the physical characteristics of the target wafer.

According to some example embodiments of the present disclosure, a method of predicting circuit characteristics of a target wafer may include collecting measured values of sample wafers among wafers manufactured in a semiconductor process and measuring one or more physical characteristics among a plurality of physical characteristics of the sample wafers; classifying the collected measured values according to process paths of the sample wafers; determining predicted values of one or more physical characteristics among the plurality of physical characteristics of the target wafer using a process path of the target wafer, the target wafer not among the sample wafers; and predicting circuit characteristics of the target wafer using measured values of the sample wafers and predicted values of the target wafer.

According to some example embodiments of the present disclosure, a process control system includes a big data collection server configured to collect, from a semiconductor fab, log data including process path information of wafers manufactured in the semiconductor fab and measured values of physical characteristics of sample wafers selected from among the manufactured wafers; a virtual measurement server configured to obtain the measured values of the sample wafers from the big data collection server, to classify the measured values according to process paths of the sample wafers, to generate predicted values of physical characteristics of unmeasured target wafers according to the classified measured values and process paths of target wafers, and to store the generated predicted values, the unmeasured target wafers being different from the sample wafers; and a characteristic prediction server configured to obtain the measured values of the sample wafers from the big data collection server, to obtain the predicted values of the target wafers from the virtual measurement server, to predict circuit characteristics of the manufactured wafers using the measured values and predicted values, and to feedback a control signal to the semiconductor fab based on the predicted circuit characteristics.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a diagram illustrating a portion of a process path in a semiconductor process;

FIGS. 2 and 3 are diagrams illustrating a process path in a semiconductor process;

FIGS. 4A and 4B are diagrams illustrating a virtual metrology method for a wafer according to an example embodiment of the present disclosure;

FIG. 5 is a diagram illustrating consistency between virtually measured predicted values and measured values according to an example embodiment of the present disclosure;

FIGS. 6A, 6B, 6C, and 6D are diagrams illustrating a comparison of predicted values between an example embodiment of the present disclosure and a comparative example;

FIG. 7 is a diagram illustrating a method for predicting circuit characteristics of a wafer according to an example embodiment of the present disclosure;

FIG. 8 is a layout diagram illustrating a semiconductor device according to an example embodiment of the present disclosure;

FIGS. 9A and 9B are cross-sectional diagrams illustrating a semiconductor device according to an example embodiment of the present disclosure;

FIGS. 10A, 10B, and 10C are graphs illustrating a correlation between physical characteristics and circuit characteristics of a wafer according to an example embodiment of the present disclosure;

FIGS. 11A, 11B, and 11C are diagrams illustrating a comparison of circuit characteristic prediction methods between an example embodiment of the present disclosure and a comparative example;

FIG. 12 is a diagram illustrating a process control system according to an example embodiment of the present disclosure; and

FIG. 13 is a diagram illustrating a virtual measurement server in FIG. 12.

### DETAILED DESCRIPTION

Hereinafter, some embodiments of the present disclosure will be described as follows with reference to the accompanying drawings.

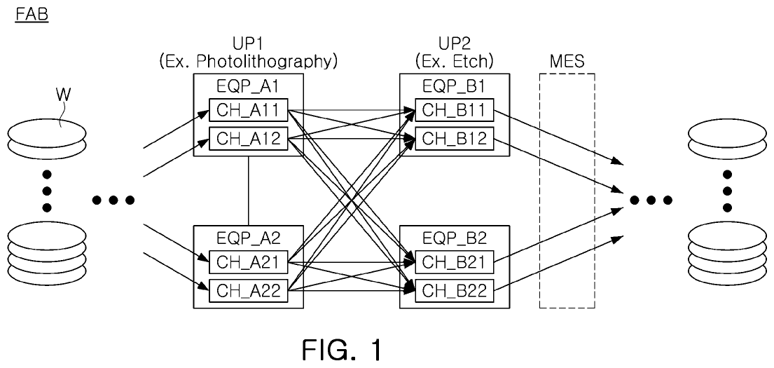

FIG. 1 is a diagram illustrating a portion of a process path in a semiconductor process.

A semiconductor device may be manufactured by performing hundreds of unit processes for forming a desired circuit pattern, including a deposition process, an exposure process, an etching process, and a planarization process, on a silicon wafer. For example, a deposition process may be performed to form a film on the wafer, a photolithography process may be performed to form a photoresist pattern on the wafer, an etching process may be performed to pattern the film formed on the wafer (using the photoresist pattern as an etching mask), and a planarization process may be performed to planarize the film formed on the wafer.

Wafers, which are objects to which a semiconductor process is performed, may be stored in a wafer cassette in units of lots and may be transferred to a process device performing each unit process. A lot may include around 24 wafers. Each unit process may be performed in units of lots, or may be performed for each wafer extracted from the wafer cassette.

A semiconductor process may provide multiple parallel processing paths for each unit process. For example, a plurality of process devices may be provided in a semiconductor fab to perform each unit process, and each process device may include a plurality of chambers.

FIG. 1 illustrates a first unit process UP1 and a second unit process UP2, which are two consecutive unit processes among a plurality of unit processes included in a semiconductor process as an example. For example, the first unit process UP1 may be an exposure process, and the second unit process UP2 may be an etching process of patterning a film formed on the wafer based on the photoresist pattern formed in the exposure process.

To perform the first unit process UP1, two devices EQP_A1 and EQP_A2 may be provided in the semiconductor fab FAB. Each of the two devices EQP_A1 and EQP_A2 may include two chambers CH_A11, CH_A12, CH_A21 and CH_A22. Similarly, two devices EQP_B1 and EQP_B2 may be provided in the semiconductor path to perform the second unit process UP2. Each of the two devices EQP_B1 and EQP_B2 may include two chambers CH_B11, CH_B12, CH_B21 and CH_B22.

The wafers W may be distributed to the plurality of chambers CH_A11, CH_A12, CH_A21, and CH_A22 to perform the first unit process UP1, and in the plurality of chambers CH_A11, CH_A12, In CH_A21 and CH_A22, the wafers W may be processed in parallel. The wafers on which the first unit process UP1 has been completed in the plurality of chambers CH_A11, CH_A12, CH_A21, and CH_A22 may be distributed to the plurality of chambers CH_B11, CH_B12, CH_B21, and CH_B22 to perform the second unit process UP2, and the wafers W may be processed in parallel in the plurality of chambers CH_B11, CH_B12, CH_B21, and CH_B22. That is, a plurality of process paths for performing the first and second unit processes UP1 and UP2 may be provided.

Physical characteristics of wafers on which the second unit process UP2 has been completed in the plurality of chambers CH_B11, CH_B12, CH_B21, and CH_B22 may be measured by a measurement device MES. As a first example, the wafers may be loaded onto optical critical dimension (OCD) measurement device. An optical critical dimension measurement method may be a method of calculating a vertical profile of a vertical pattern formed on a wafer by inverting reflectivity and phase information of light diffracted through the vertical pattern. The optical critical dimension measurement device may measure vertical profiles such as a depth and height of patterns etched on the wafer. As a second example, the wafers may be loaded onto a stage of a scanning electron microscope (SEM). The electron microscope may measure horizontal profiles such as a width and length of patterns formed on the wafer.

Physical characteristics measured by a measurement device (MES) may be a basis for predicting circuit characteristics of a semiconductor device formed on a wafer and may be a basis for determining quality of the semiconductor device. However, measuring the physical characteristics of overall wafers (i.e., all of the wafers) manufactured in the semiconductor process 10 may cause an increase in wafer manufacturing time. Accordingly, virtual measurement may be performed in which a portion or sample of the wafers is selected and physical characteristics thereof may be measured, and values of other wafers may be predicted using the measurements of the sample wafers and without measuring physical characteristics of the other wafers.

For example, to predict the depth of patterns etched on a target (unmeasured) wafer for which virtual measurement is to be performed, historical data of a device performing the second unit process UP2 and measured values of sample wafers may be used. The history data may include process variables used to etch the patterns on each wafer in the device, for example, voltage values applied to upper and lower portions of the wafer for etching and the time at which the voltage was applied. When the target wafer is etched in the chamber CH_B11, history data of the device EQP_B1 may be searched for, and data corresponding to sample wafers on which an etching process has been performed using the same process parameters as those of the target wafer and in the chamber CH_B11 may be selected. A measurement value of the target wafer may be predicted based on measured values of sample wafers measured by the metrology device (MES) among the selected wafers.

However, since the physical characteristics of a wafer may be affected by numerous unit processes, it may be difficult to predict measurement values accurately using only historical data in a specific device or chamber. For example, the depth of the etched patterns may be affected by the value of the voltage applied for etching in the second unit process UP2 and the time during which the voltage was applied, and also by the widths of the patterns formed in the preceding first unit process UP1. Since the first unit process UP1 may be performed in different chambers even for wafers etched in the same chamber CH_B11, there may be a process difference in the widths of formed patterns. Accordingly, it may be difficult to predict the measurement value accurately using only process variables related to the second unit process UP2. Also, since the entirety of the history data of a specific device may need to be searched for, virtual measurement may take a long time.

In some example embodiments, process path information of a target wafer may be used for virtual measurement. The process path information may include information indicating, for each measured wafer, which chamber and which device the wafer was processed in during each unit process and under which process conditions. Here, the process conditions may also be referred to as a process program identifier (PPID), recipe, or the like. Wafers manufactured in a similar time period through the same process path in the semiconductor process 10 may have substantially the same physical characteristics.

Log data may be collected indicating which wafers were manufactured or processed in the semiconductor process 10 in which chamber of which device in each unit process and under which process conditions. Also, measured values may be collected for sample wafers of which physical characteristics have been measured among the wafers. The collected measured values may be classified by process path.

In some example embodiments, to predict physical characteristics of a target wafer, measured values of sample wafers having the same process path as that of the target wafer may be used. For example, to predict the depth of the etched pattern of the target wafer, a moving average value of measured values of sample wafers having the same process path as that of the target wafer may be determined as the predicted value of the depth of the etched pattern.

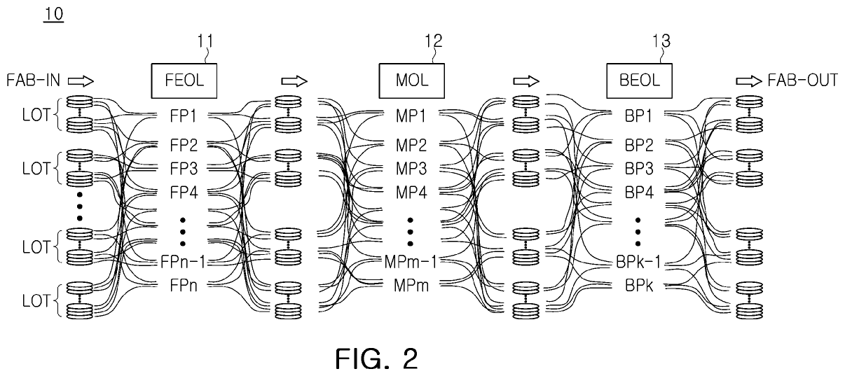

In some example embodiments, since the predicted value may be generated based on measured values of the sample wafers having the same process path as that of the target wafer, accuracy of virtual measurement may improve. Also, since the measured values classified for each process path may be used without searching the overall history data related to the physical characteristics to be predicted, the time for virtual measurement may be reduced. Hereinafter, some example embodiments will be described in greater detail with reference to FIGS. 2 to 13.

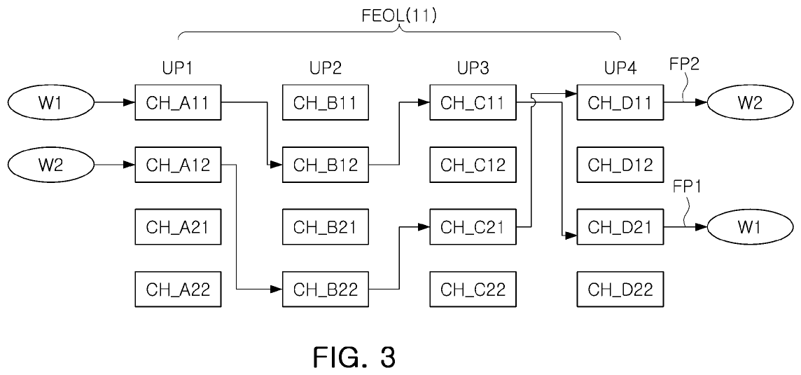

FIGS. 2 and 3 are diagrams illustrating a process path in a semiconductor process. FIG. 2 is a diagram illustrating an entire process path of the semiconductor process 10, and FIG. 3 is a diagram illustrating a portion of the process path of the semiconductor process 10 in greater detail.

Referring to FIG. 2, a semiconductor process 10 may include a front-end-of-line (FEOL) process 11, a middle-of-line (MOL) process 12, and a back-end-of-line (BEOL) process 13.

The FEOL process 11 may include, for example, planarization and cleaning of the wafer, forming trenches, forming wells, forming gate electrodes, and forming sources and drains. Circuit components such as transistors may be formed on a wafer by the FEOL process 11.

The BEOL process 13 may include silicidating the gate, source and drain regions, adding a dielectric, planarizing, forming holes, adding a metal layer, forming vias, and forming a passivation layer. The circuit components may be interconnected by the BEOL process 13.

The MOL process 12 may be performed between the FEOL process 11 and the BEOL process 13, and contacts may be formed on the circuit components by the MOL process 12.

Wafers may be stored in wafer cassettes in units of lots (LOT) and may be fab-in to semiconductor fabs, and may be transferred in sequence between process devices of the FEOL process 11, process devices of the MOL process 12, process devices of the BEOL process 13. When overall processes are completed, the wafers may be fab-out from the semiconductor process.

Each of the FEOL process 11, the MOL process 12, and the BEOL process 13 may include a plurality of unit processes. As described with reference to FIG. 1, a plurality of devices for performing each unit process in parallel may be provided. Depending on which device wafers are processed in each unit process, multiple process paths may be formed.

Referring to FIG. 3, the FEOL process 11 may include four unit processes UP1-UP4. A plurality of chambers CH for performing unit processes in parallel may be provided. Wafers may be transferred to an arbitrary chamber in each unit process, and a process path may be formed depending on which chamber and under which process conditions the wafers are processed.

For example, the first wafer W1 may be processed while moving along the chambers CH_A11, CH_B12, CH_C11, and CH_D21, and the second wafer W2 may be processed while moving along the other chambers CH_A12, CH_B22, CH_C21, and CH_D11. The chambers CH_A11, CH_B12, CH_C11, and CH_D21 may form a first FEOL process path FP1, and the chambers CH_A12, CH_B22, CH_C21, and CH_D11 may form a second FEOL process path FP2.

Different chambers in which the same unit process is performed may have subtle process differences. Accordingly, wafers processed through different process paths may have different physical characteristics, and wafers processed through the same process path may have substantially the same physical characteristics.

Referring back to FIG. 2, an n number of FEOL process paths FP1-FPn may be formed in the FEOL process 11, an m number of MOL process paths MP1-MPn may be formed in the MOL process 12, and a k number of BEOL process paths BP1-BPk may be formed in the BEOL process 13.

In some example embodiments, measured values of sample wafers for physical characteristics of the wafer may be collected, and the collected measured values may be classified according to process paths. The measured values as classified according to the process paths may be used to generate predicted values for physical characteristics of target wafers.

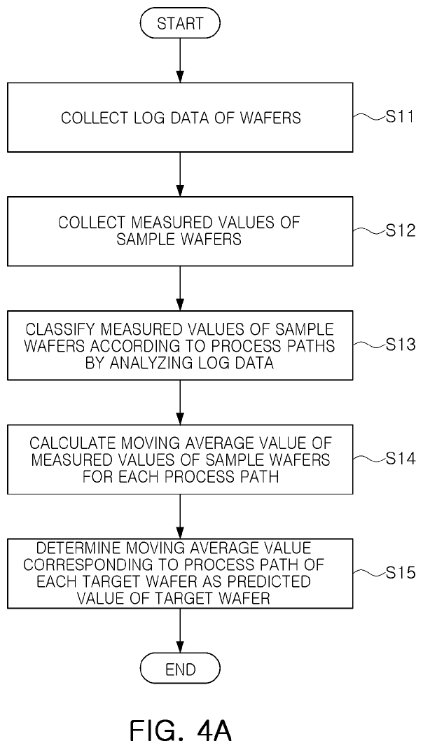

In some example embodiments, the collected measured values may, depending on the type of physical characteristics, be classified according to FEOL process paths FP1-FPn, MOL process paths MP1-MPn, and/or BEOL process paths BP1-BPk. For example, the depth of the trench formed on the surface of the wafer in the FEOL process 11 may be affected by a plurality of unit processes included in the FEOL process 11, but may not be affected by the MOL process 12 and the BEOL process 13. That is, the depth of the trench may be independent of the MOL process 12 and the BEOL process 13. Accordingly, the measured values of the trench depth may be classified according to FEOL process paths FP1 to FPn. Hereinafter, a virtual metrology method for a wafer according to some example embodiments will be described in greater detail with reference to FIGS. 4A and 4B.

FIGS. 4A and 4B are diagrams illustrating a virtual metrology method for a wafer according to some example embodiments.

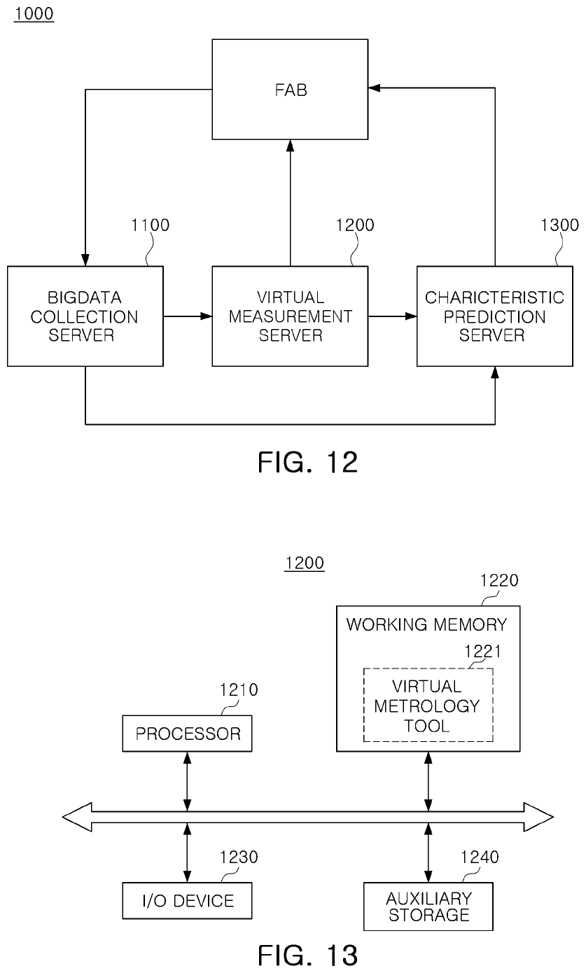

Referring to FIG. 4A, the virtual metrology method in some example embodiments may start from operation S11. In operation S11, log data may be collected of wafers manufactured in a semiconductor process. For example, an identifier may be assigned to each of the wafers. When a wafer assigned with an identifier moves to a process device for performing each unit process, log data indicating the process device in which the unit process was performed on the wafer may be transmitted from the semiconductor fab to a big data collection server (e.g., a collection server, which may the big data collection server 1100 seen and described with reference to FIG. 12, below), and the big data collection server may store log data corresponding to each wafer.

In operation S12, measured values of sample wafers may be collected. Specifically, a portion of wafers among wafers manufactured in a semiconductor fab may be sampled. For example, about 10% of wafers among the manufactured wafers may be randomly sampled. Sample wafers may be transferred to a measurement device included in a semiconductor fab, and measured values may be generated by measuring physical characteristics of the sample wafers by the measurement device. The measured values may be transmitted from the semiconductor fab to the big data collection server, and the big data collection server may store measured values corresponding to each sample wafer.

In operation S13, the log data may be analyzed, and the measured values of the sample wafers may be classified according to process paths. For example, log data and measured values of the sample wafers stored by the big data collection server may be provided to a virtual measurement server (which may the virtual measurement server 1200 seen and described with reference to FIG. 12, below). Since the wafers may be distinguished by identifiers, the measured values of sample wafers and log data of the sample wafers may be mapped. Accordingly, the virtual measurement server may distinguish the measured values by identifying which process path the sample wafers having the measured values have gone through, and may classify or group measured values of the sample wafers having the same process path.

In operation S14, moving average values of measured values of sample wafers for each process path may be calculated. A process device may deteriorate and/or may be repaired over time. Accordingly, even the wafers manufactured through the same process path may have differences in physical characteristics depending on the manufacturing time thereof. Accordingly, the virtual measurement server may calculate a moving average value based on measured values of sample wafers manufactured in a predetermined period from the reference time point.

In operation S15, a moving average value corresponding to the same process path as that of the target wafer may be determined as the predicted value of the target wafer. The target wafer may be an object to which or on which a virtual measurement is performed, and may refer to a wafer not measured by the measurement device among wafers manufactured in a semiconductor process. The virtual measurement server may obtain log data of target wafers from the big data collection server, and may determine a process path of each of the target wafers by analyzing the obtained log data. Also, the virtual measurement server may complete the virtual measurement by determining a moving average value corresponding to the same process path for each of the target wafers as the predicted value. Meanwhile, the virtual measurement server may store predicted values in the server.

Referring to FIG. 4B, operation S14 in FIG. 4A may include operations S141 to S144.

In operation S141, measured values of sample wafers manufactured within the first period from the reference time point may be obtained. For example, the reference time point may be a time point at which the virtual measurement is performed or a time point at which a target wafer is manufactured. The first period may vary in some example embodiments, and may be a period of one day. The log data of the sample wafers stored by the big data collection server may include manufacturing time information of the sample wafers. The big data collection server may provide measured values and log data of sample wafers manufactured within the first period to the virtual measurement server based on the manufacturing time information.

In operation S142, it may be determined whether sufficient data of sample wafers is collected and/or has been collected for each process path. Herein, sufficient data may refer to an amount of measured values and log data sufficient to determine a predicted value at a statistically significant level based on the average value of measured values, and may be experimentally determined in advance. In the case in which the operation of a portion of process device is stopped during the first period, it may be difficult to obtain statistically significant data for a portion of process paths.

In the case in which sufficient data is not collected for overall process paths (“No” in operation S142), the range of the first period may be increased in operation S143, and additional data may be collected in operation S141. For example, in the case in which the amount of data is not sufficient when the virtual measurement server collects data up to one day from the time point at which the target wafer is manufactured, data for the previous day may be further collected.

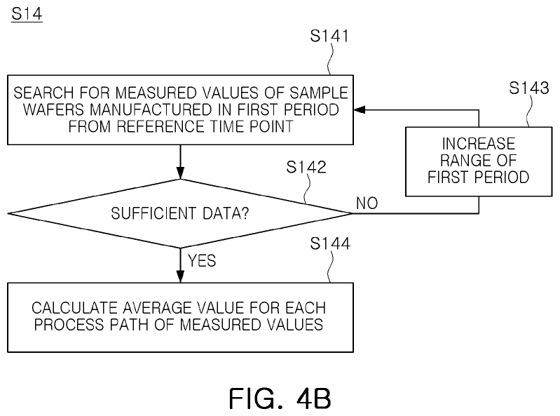

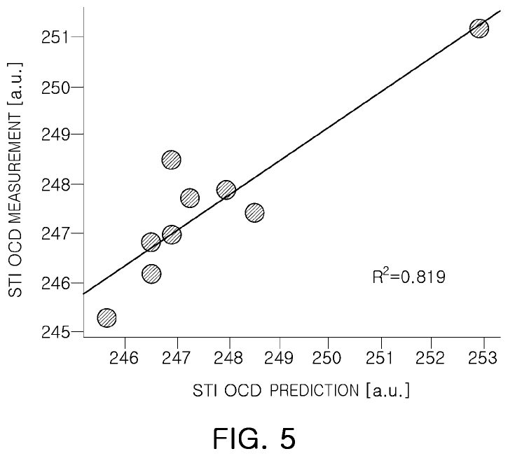

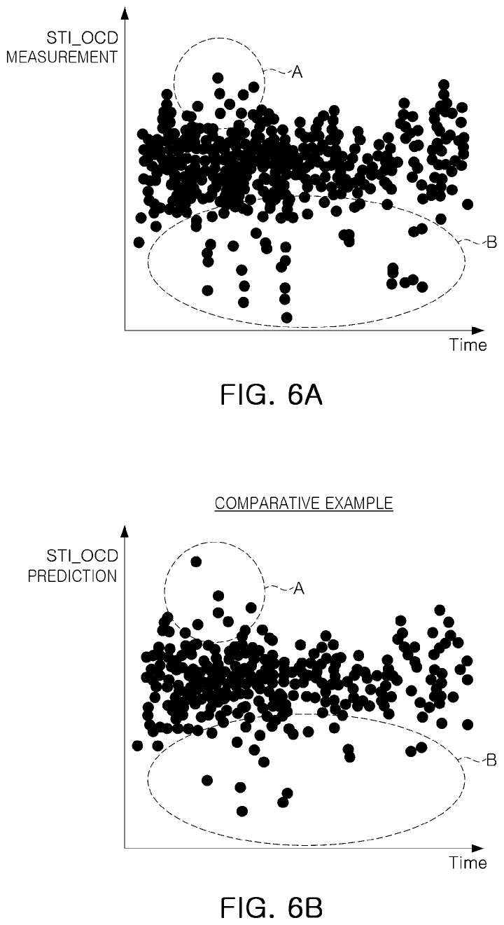

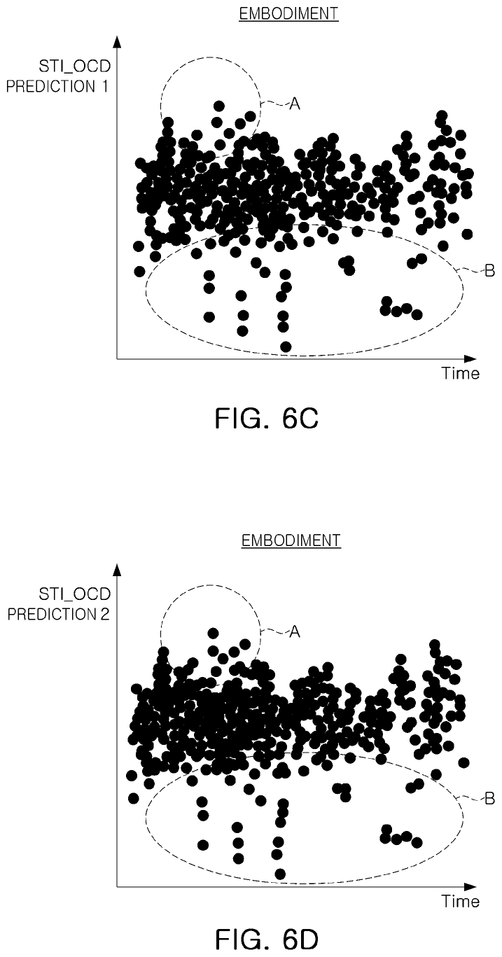

In the case in which sufficient data is collected for overall process paths (“Yes” in operation S142), the average value for each process path in the first period of the measured values may be calculated in operation S144, thereby completing the calculation of the moving average value. Hereinafter, effects of the virtual metrology method in an example embodiment will be described with reference to FIGS. 5 to 6D.

FIG. 5 is a diagram illustrating consistency between virtually measured predicted values and measured values according to some example embodiments.

The graph in FIG. 5 is a comparison between values obtained by predicting the optical critical dimension of shallow trench isolation (STI) formed on target wafers in some example embodiments and values obtained by measuring the optical critical dimension of the STI of the target wafers. The horizontal axis of the graph in FIG. 5 represents the predicted value of the optical critical dimension in the example embodiment, and the vertical axis represents the measured value of the optical critical dimension. An arbitrary unit (a.u.: arbitrary unit) may be used for the predicted value and the measured value. The measured values and the predicted values illustrated in the graph in FIG. 5 may have a correlation coefficient of 0.819. In some example embodiments, a predicted value with high consistency may be obtained based on measured values of sample wafers having the same process path as that of the target wafer.

FIGS. 6A to 6D are diagrams illustrating a comparison of predicted values between some example embodiments of the present disclosure and a comparative example.

FIG. 6A illustrates measured values (that is, actual measured values) of the optical critical dimension of STI over time. FIG. 6B illustrates predicted values of the optical critical dimension of the STI according to a comparative example different from the example embodiment. Specifically, the comparative example may correspond to a virtual metrology method for generating a predicted value from historical data of a specific device forming STI.

FIGS. 6C and 6D illustrate predicted values of the optical critical dimension of the STI according to some example embodiments. Specifically, FIG. 6C illustrates an example in which a predicted value is generated based on measured values of STI obtained for one day before a reference time point, and FIG. 6D illustrates an example in which a predicted value is generated based on measured values of STI obtained for two days before a reference time point.

Comparing FIGS. 6A and 6B, the measured values of the optical critical dimension and the predicted values according to the comparative example may be different. Specifically, when regions A and B in FIGS. 6A and 6B are compared, the number of measured values included in regions A and B in FIG. 6A may be greater than the number of predicted values included in regions A and B in FIG. 6B. That is, the virtual metrology method according to the comparative example may not predict accurately the measured values when the measured values are beyond the average. Accordingly, when virtual measurement is performed using only the history data of a specific device, it may not be possible to detect whether a wafer that has not been measured is defective or whether a process is abnormal.

Comparing FIGS. 6A and 6C, there may be almost no difference between the measured values of the optical critical dimension and the predicted values in the example embodiment. Specifically, when regions A and B in FIGS. 6A and 6C are compared, the number of measured values and positions thereof included in regions A and B in FIG. 6A may be similar to the number of predicted values and positions thereof included in regions A and B of FIG. 6C. In FIG. 6D, similarly, positions of predicted values may be similar to positions of measured values in FIG. 6A.

That is, the virtual metrology method in the example embodiments may generate predicted values which may be highly consistent with measured values. Accordingly, defects in wafers not having been measured may be effectively detected, and abnormalities in a process may be detected.

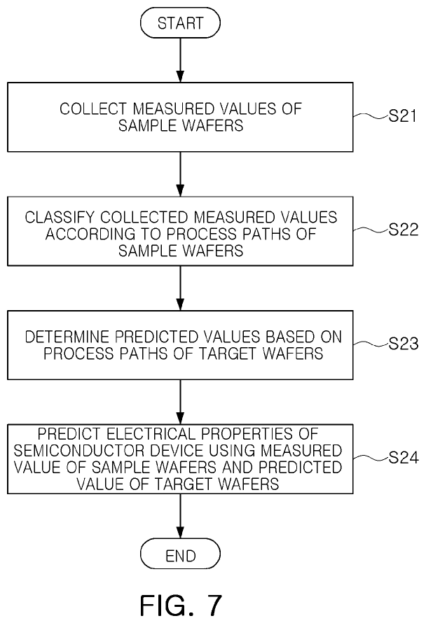

Meanwhile, circuit characteristics of a semiconductor device formed on wafers may be predicted using predicted values generated by performing virtual measurement on wafers which have not been measured. In some example embodiments, circuit characteristics of wafers of which physical characteristics have not been measured may be effectively predicted. Hereinafter, a method for predicting circuit characteristics of a wafer in some example embodiments will be described in detail with reference to FIG. 7.

FIG. 7 is a diagram illustrating a method for predicting circuit characteristics of a wafer according to some example embodiments.

Referring to FIG. 7, the method for predicting circuit characteristics of a wafer in some example embodiments may start from operation S21. In operation S21, measured values of sample wafers may be collected. In operation S22, the collected measured values may be classified according to process paths of the sample wafers. In operation S23, predicted values of the target wafers may be determined based on the classified measured values and process paths of target wafers which have not been measured.

Operations S21 to S23 may correspond to the virtual metrology method of operations S11 to S15 described with reference to FIG. 4A. When operations S21 to S23 are performed, measured values may be collected for sample wafers among manufactured wafers, and predicted values may be collected for target wafers which have not been measured.

In operation S24, circuit characteristics of a semiconductor device formed on the wafer may be predicted using the measured values of the sample wafers and the predicted values of the target wafers. Circuit characteristics of a semiconductor device may be affected by physical characteristics such as a width, height, and depth of patterns formed on a wafer. Specific circuit characteristics may be influenced by two or more types of physical characteristics. A correlation between circuit characteristics to be predicted and physical characteristics may be determined in advance using regression analysis. Circuit characteristics of sample wafers may be predicted based on measured values and the correlation, and circuit characteristics of target wafers may be predicted based on the predicted values and the correlation.

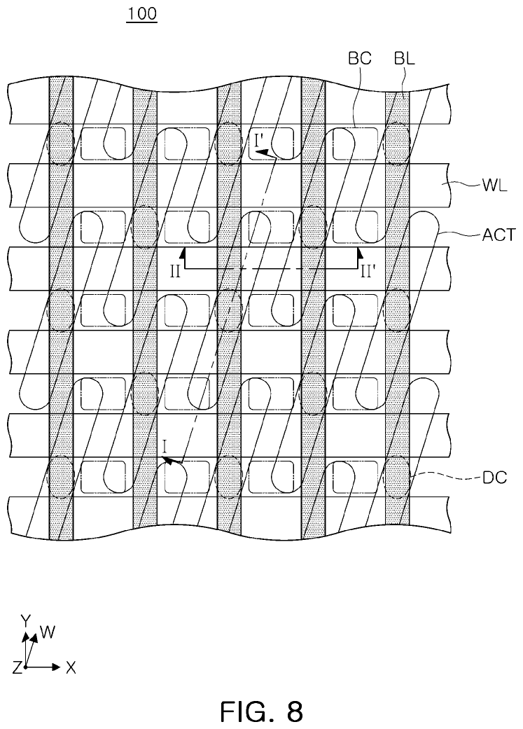

Hereinafter, some examples of correlations between circuit characteristics and physical characteristics of semiconductor devices will be described in detail with reference to FIGS. 8 to 10C.

FIG. 8 is a layout diagram illustrating a semiconductor device according to some example embodiments.

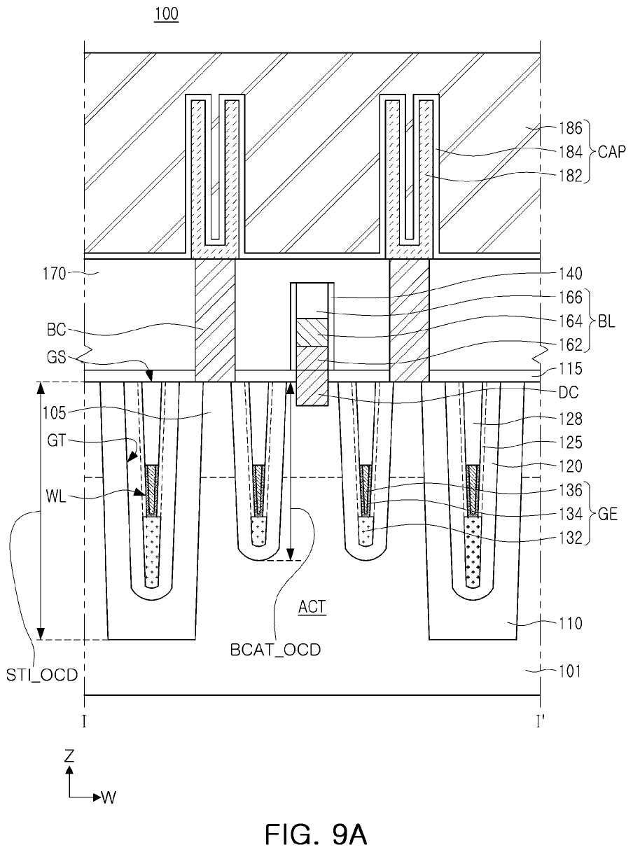

FIGS. 9A and 9B are cross-sectional diagrams illustrating a semiconductor device according to some example embodiments. FIG. 9A is a cross-sectional diagram taken along line I-I′ in FIG. 8, and FIG. 9B is a cross-sectional diagram taken along line II-II′ in FIG. 8.

Referring to FIGS. 8 to 9B, the semiconductor device 100 may include a substrate 101 including active regions ACT, gate structures GS buried and extended in the substrate 101 and each including a word line WL, bit lines BL extending and crossing or intersecting the word line WL on the substrate 101, direct contacts DC electrically connecting the bit lines BL and the active regions ACT, capacitors CAP on the bit lines BL, and storage node contacts BC electrically connecting the capacitors CAP to the active regions ACT. The semiconductor device 100 may include device isolation films 110 that define active regions ACT, a lower insulating layer 115 and an interlayer insulating layer 170 on the substrate 101, and bit line spacers 140 on the side surfaces of the bit lines BL. The semiconductor device 100 may be applied to, for example, a cell array region of a dynamic random access memory (DRAM), but the present disclosure is not limited thereto.

The substrate 101 may have an upper surface extending in the X- and Y-directions. The active regions ACT may be defined within the substrate 101 by device isolation layers 110. The active regions ACT may have a bar shape and may be arranged in an island shape extending in one direction, for example, the W direction, within the substrate 101. to the extension directions of the word lines WL and bit lines BL. The W direction may be angled with respect to the X- and Y-directions.

The active regions ACT may have impurity regions 105 having a predetermined depth from the upper surface of the substrate 101. The impurity region 105 may be provided as a source/drain region of a transistor by the gate structure GS. For example, a drain region may be formed between two gate structures GS intersecting one active region ACT, and a source region may be formed outside each of the two gate structures GS. The source region and the drain region may be formed by the impurity region 105 by doping or ion implantation of substantially the same impurities, and may be referred to interchangeably depending on a circuit configuration of a finally formed transistor. The impurity region 105 may be formed to a depth lower than a level of the upper surface of the gate electrode layer GE, but an example embodiment thereof is not limited thereto. Also, in example embodiments, the impurity region 105 may have different depths in the source region and the drain region.

The device isolation layers 110 may be formed by a shallow trench isolation (STI) process. The device isolation layers 110 may electrically isolate the active regions ACT from each other while surrounding the regions. The device isolation layers 110 may be formed of an insulating material, for example, an oxide, a nitride, or a combination thereof.

Meanwhile, the depth of the STI for forming the device isolation layers 110 may affect the threshold voltage VTS of the gate structures GS. To predict the threshold voltage VTS, after the etching process for forming the device isolation layers 110 is completed, the depth of the STI may be measured by an optical critical dimension method. In FIG. 9A, the depth STI_OCD of STI which may be measured by the optical critical dimension method is indicated.

The gate structures GS may include word lines WL and may be in gate trenches GT extending from the upper surface of the substrate 101. The gate structures GS may extend in one direction, for example, in the X-direction, by intersecting the active regions ACT in the substrate 101. For example, a pair of gate structures GS may intersect one active region ACT. Each of the gate structures GS may include buried word lines WL included in a buried channel array transistor (BCAT). Each gate structure GS may include a gate dielectric layer 120, sidewall insulating layers 125, a gate electrode layer GE, and a filling insulating layer 128.

The depth of the BCAT may affect the threshold voltage VTS of the gate structures GS. To predict the threshold voltage VTS, after the etching process for forming the gate structures GS is completed, the depth of the BCAT may be measured by an optical critical dimension method. In FIG. 9A, the depth BCAT_OCD of the BCAT which may be measured by the optical critical dimension method is indicated.

The gate trenches GT may have a relatively deeper depth in the device isolation layers 110 than in the active regions ACT. Accordingly, as illustrated in FIG. 9B, the gate electrode layer GE may extend from above the active regions ACT while partially enclosing side surfaces of the active regions ACT.

The gate dielectric layer 120 may be on a bottom surface and internal side surfaces of the gate trench GT. The gate dielectric layer 120 may include at least one of oxide, nitride, and oxynitride. The gate dielectric layer 120 may be, for example, a silicon oxide layer or an insulating layer having a high dielectric constant. In example embodiments, the gate dielectric layer 120 may be formed by oxidizing the active region ACT or formed by deposition.

The sidewall insulating layers 125 may be provided at a predetermined depth from an upper portion of the gate trench GT. In the gate trench GT, the sidewall insulating layers 125 may be on the upper surface of the first conductive layer 132 and may be on internal side surfaces of the gate dielectric layer 120. For example, the sidewall insulating layers 125 may be silicon oxide films. The sidewall insulating layers 125 may include the same material as that of the gate dielectric layer 120 or may include a different material. When the sidewall insulating layers 125 are formed of the same material as that of the gate dielectric layer 120, an interfacial surface with the gate dielectric layer 120 may not be distinguished. However, even in this case, the region in which the sidewall insulating layers 125 are formed may be recognized by a difference in width from the region in which the sidewall insulating layers 125 are not formed.

The gate electrode layer GE may include a first conductive layer 132 below the gate trench GT, a second conductive layer 134 on the gate dielectric layer 120 on the upper surface of the first conductive layer 132, and a third conductive layer 136 in a region between the second conductive layers 134.

The first conductive layer 132 may fill the gap between the gate dielectric layers 120 below the gate trench GT and may be provided with a predetermined length or height. The first conductive layer 132 may be a first metal layer including a metal material, and may include, for example, at least one of titanium (Ti), titanium nitride (TiN), tantalum (Ta), and tantalum nitride (TaN). For example, the first conductive layer 132 may be formed as a double layer of titanium (Ti) and titanium nitride (TiN).

The second conductive layer 134 may extend from the lower portion of the sidewall insulating layers 125 in a liner form to cover internal side surfaces of the sidewall insulating layers 125 and the upper surface of the first conductive layer 132. The second conductive layer 134 may extend to a substantially uniform thickness. An upper surface of the second conductive layer 134 may be in contact with the filling insulating layer 128. The second conductive layer 134 may be interposed between the first conductive layer 132 and the third conductive layer 136 and may surround external side and lower surfaces of the third conductive layer 136. The second conductive layer 134 may be surrounded by the first conductive layer 132, the sidewall insulating layers 125, the third conductive layer 136, and the filling insulating layer 128. Due to the sidewall insulating layers 125, in a region adjacent to the interfacial surface between the first conductive layer 132 and the second conductive layer 134, the width W2 of the second conductive layer 134 may be smaller than the width W1 of the first conductive layer 132. The second conductive layer 134 may have a two-dimensional honeycomb structure consisting of one layer or multiple layers of carbon atoms. Since graphene has relatively low resistivity, entire resistance of the gate electrode layer GE may be reduced by the second conductive layer 134. The second conductive layer 134 may have a third thickness T3 ranging from about 6 Å to about 50 Å.

The third conductive layer 136 may be arranged such that external side surfaces and lower surfaces are surrounded by the second conductive layer 134. An upper surface of the third conductive layer 136 may be substantially coplanar with an upper surface of the second conductive layer 134. The third conductive layer 136 may be a second metal layer including a metal material, and may include, for example, at least one of titanium (Ti), titanium nitride (TiN), tantalum (Ta), and tantalum nitride (TaN). For example, the third conductive layer 136 may include the same material as that of the first conductive layer 132 or may be formed of the same material as that of the first conductive layer 132.

In the gate electrode layer GE, the first conductive layer 132 may be in contact with the gate dielectric layer 120 and may form a gate portion included in a transistor. In the gate electrode layer GE, the second conductive layer 134 and the third conductive layer 136 in the sidewall insulating layers 125 may form a word line portion functioning as a word line WL.

The filling insulating layer 128 may fill the gate trench GT on the second conductive layer 134 and the third conductive layer 136. The filling insulating layer 128 may be formed of an insulating material, for example, a silicon nitride film.

The active regions ACT may have a FinFET structure. The height of the fin structure of the active regions ACT may affect the threshold voltage VTS of the gate structure GS. To estimate the threshold voltage VTS, the height of the fin structure may be measured by an optical critical order method or optical critical dimension method. The height of the fin structure (FIN_OCD) measured by the optical critical order method or optical critical dimension method is illustrated in FIG. 9B.

The direct contact DC may be between two adjacent bit lines BL and may be connected to a drain region of the active region ACT. The direct contact DC may penetrate or extend through the lower insulating layer 115 and may be electrically connect the drain region to the bit line BL. The storage node contact BC may be connected to a source region of the active region ACT. The storage node contact BC may penetrate or extend through the lower insulating layer 115 and the interlayer insulating layer 170 and may electrically connect the source region to the capacitor CAP. The storage node contacts BC may be arranged in a row in the X- and Y-directions. In some example embodiments, the shape and structure of the direct contact DC and the storage node contacts BC may be varied. For example, separate contact spacers may be further on side surfaces of the direct contact DC. For example, the storage node contacts BC may be recessed into the substrate 101 and may include landing pads thereon.

The direct contact DC and the storage node contact BC may be formed of a conductive material, and may include, for example, polycrystalline silicon and/or a metal material.

The lower insulating layer 115 and the interlayer insulating layer 170 may cover the upper surface of the substrate 101. The lower insulating layer 115 and the interlayer insulating layer 170 may include an insulating material, and may include, for example, at least one of oxide, nitride, and oxynitride.

The bit lines BL may extend in one direction perpendicular to the gate structure GS, for example, in the Y-direction. The bit lines BL may include a first bit line conductive layer 162, a second bit line conductive layer 164 on the first bit line conductive layer 162, and a capping layer 166 on the second bit line conductive layer 164. The first bit line conductive layer 162 may be a semiconductor layer and may be in contact with the upper surface of the direct contact DC. The second bit line conductive layer 164 may include a metal material, and may include, for example, a double layer of a metal layer and a metal silicide layer. The capping layer 166 may include an insulating material.

The bit line spacers 140 may be on both sidewalls of the bit lines BL. The bit line spacers 140 may be formed of an oxide layer, a nitride layer, an air spacer, or a combination thereof. The air spacer may include gases present in the atmosphere or during a manufacturing process of a semiconductor device.

The capacitor CAP may include a lower electrode 182, a capacitor dielectric layer 184, and an upper electrode 186. The lower electrode 182 and the upper electrode 186 may include at least one of a doped semiconductor, a metal nitride, a metal, and a metal oxide. The lower electrode 182 and the upper electrode 186 may include, for example, at least one of polycrystalline silicon, titanium nitride (TiN), tungsten (W), titanium (Ti), ruthenium (Ru), and tungsten nitride (WN). The capacitor dielectric layer 184 may include, for example, at least one of high-k materials such as zirconium oxide (ZrO2), aluminum oxide (Al2O3), and hafnium oxide (Hf2O3). The capacitor CAP is illustrated in a cylinder shape, but the present disclosure is not limited thereto, and the capacitor CAP may have a pillar shape in example embodiments.

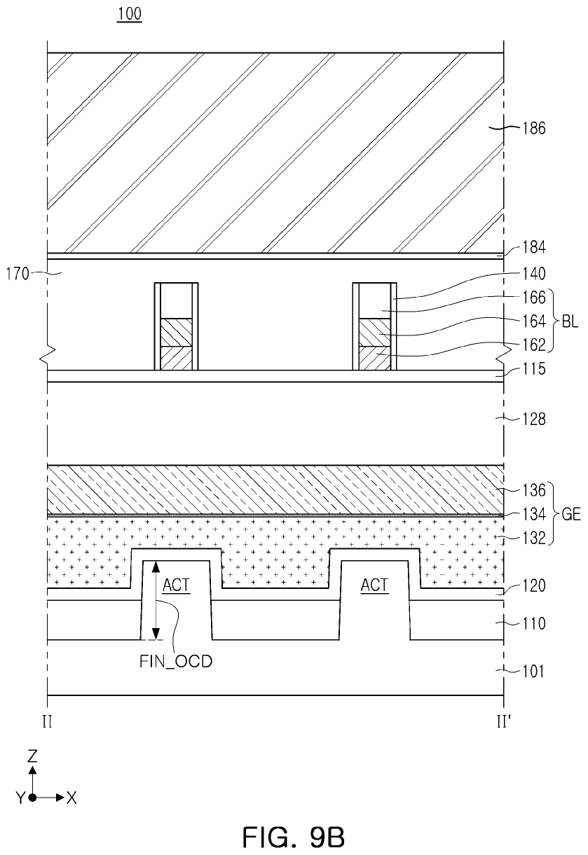

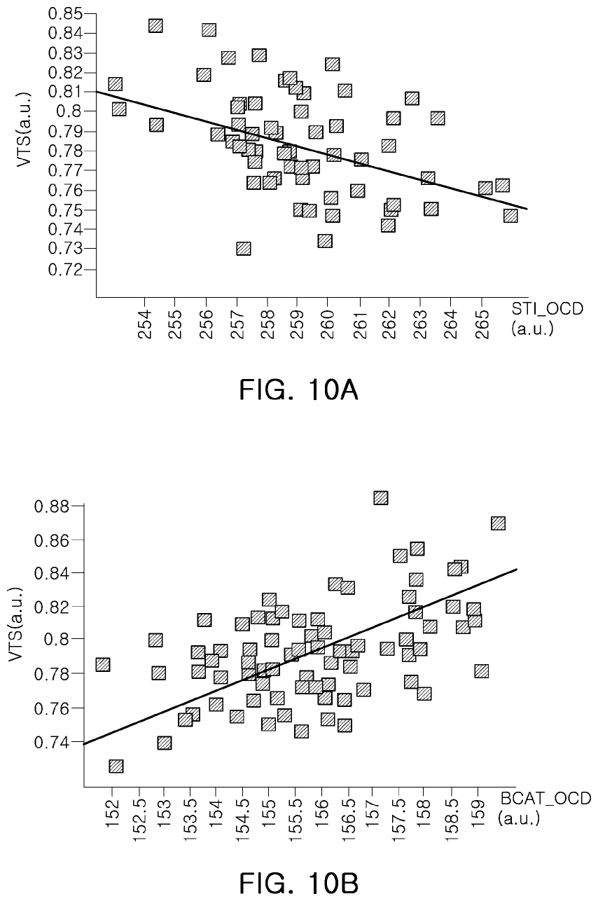

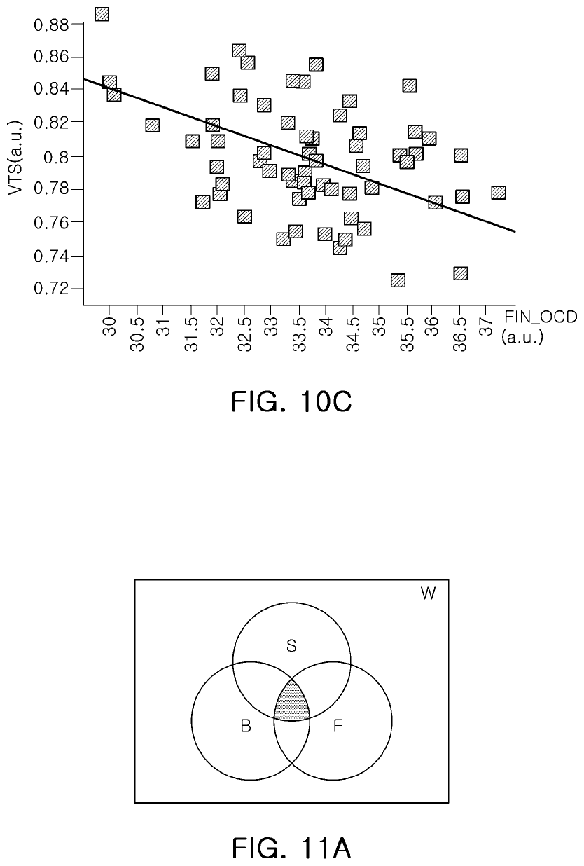

FIGS. 10A to 10C are graphs illustrating a correlation between physical characteristics and circuit characteristics of a wafer according to some example embodiments. FIG. 10A illustrates a relationship between a threshold voltage VTS of a gate structure and a depth STI_OCD of STI, which is an example of circuit characteristics, and FIG. 10B illustrates the relationship between a threshold voltage VTS and a depth BCAT_OCD of BCAT. FIG. 10C illustrates the relationship between the threshold voltage VTS and the height FIN_OCD of FIN. Arbitrary units (a.u.) may be used as units of the threshold voltage VTS and the physical characteristics STI_OCD, BCAT_OCD, and FIN_OCD.

In the examples in FIGS. 10A to 10C, a correlation coefficient between each of the physical characteristics and the circuit characteristics may be derived by a regression analysis method.

Based on the correlation coefficient between each physical characteristic and the circuit characteristic, a regression analysis equation for determining the circuit characteristic value based on the measured values of the physical characteristics may be derived as in [Equation 1] below.

VTS=α1·STI+α₂·BCAT+α₃·FIN+C [Equation 1]

Here, VTS denotes the threshold voltage of the gate structure, STI denotes the depth of STI, BCAT denotes the depth of BCAT, and FIN denotes the height of FIN. a₁, a₂ and a₃ denote correlation coefficients of the depth of STI, the depth of BCAT, and the height of FIN with respect to VTS, respectively, and C is a constant.

In some example embodiments, physical characteristics STI_OCD, BCAT_OCD, and FIN_OCD may be predicted even for a wafer on which a portion of or the entirety of the physical characteristics STI_OCD, BCAT_OCD, and FIN_OCD are not measured. Using predicted values of physical characteristics STI, BCAT, and FIN and a predetermined multiple regression analysis equation, circuit characteristics VTS may be predicted even for unmeasured wafers.

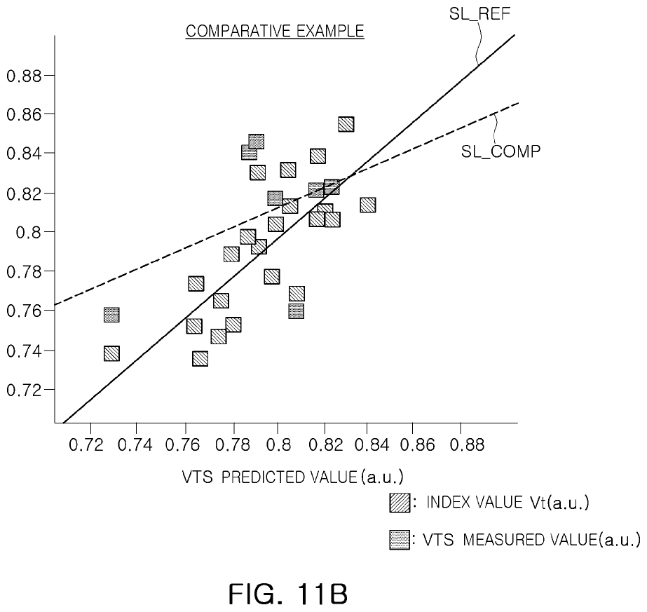

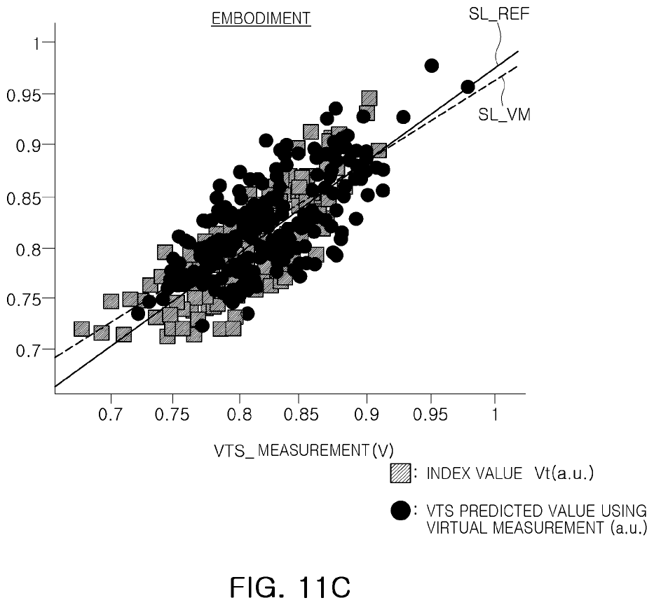

FIGS. 11A to 11C are diagrams illustrating a comparison of circuit characteristic prediction methods between some example embodiments of the present disclosure and a comparative example. The comparative example corresponds to a method of predicting circuit characteristics of a wafer using only measured values of physical characteristics.

FIG. 11A is a diagram illustrating limitations of a method for predicting circuit characteristics of a wafer according to a comparative example. The Venn diagram illustrated in FIG. 11A indicates a set (S) of sample wafers of which the depth of STI is measured, a set (B) of sample wafers of which the depth of BCAT is measured, and a set (F) of sample wafers of which the height of the fin structure is measured in the set (W) of the entirety of manufactured wafers.

Different physical characteristics determined in different processes may be measured by different measurement device. Each of the measurement device included in the semiconductor fab may arbitrarily select sample wafers and may perform measurement. When sample wafers are randomly selected in each measurement device, even when specific physical characteristics are measured in one sample wafer, other physical characteristics may not be measured.

For example, in each measurement device for measuring the physical characteristics STI_OCD, BCAT_OCD, and FIN_OCD, sample wafers of a predetermined ratio among overall wafers may be randomly selected. When 10% of the wafers are randomly selected from each measurement device, the number of sample wafers having measured values for overall physical characteristics STI_OCD, BCAT_OCD, and FIN_OCD required to predict circuit characteristics may be only 0.1% (=10%*10%*10%) of the total number of wafers. In FIG. 11A, only wafers belonging to the shaded region may have measured values for overall physical characteristics STI_OCD, BCAT_OCD, and FIN_OCD.

To predict circuit characteristics of a wafer, measured values for overall physical characteristics correlated with the circuit characteristics may be required. When trying to predict circuit characteristics based on measured values of physical characteristics, the number of wafers of which circuit characteristics may be predicted may be smaller, and may be significantly smaller, than the total number of manufactured wafers.

In some example embodiments, with respect to wafers on which at least a portion of the physical characteristics are not measured, predicted values for physical characteristics not measured may be generated by virtual measurement. Also, circuit characteristics of wafers may be predicted based on predicted values of physical characteristics. Accordingly, even when physical characteristics of a portion of sample wafers are measured, circuit characteristics of the entirety of the manufactured wafers W may be predicted.

FIG. 11B is a graph illustrating a correlation between predicted circuit characteristics and measured circuit characteristics according to a comparative example. The horizontal axis of the graph in FIG. 11B represents the predicted value of the threshold voltage VTS predicted according to a comparative example, and the vertical axis represents an index value Vt of the threshold voltage corresponding to the threshold voltage VTS and the measured value of the threshold voltage VTS. Arbitrary units (a.u.) may be used as units of the threshold voltage VTS and the index value Vt of the threshold voltage. The index value Vt of the threshold voltage may be a threshold voltage value determined by applying a voltage to a word line and testing whether current flows through a bit line after packaging of a semiconductor device included in a wafer is completed, and is known to be highly consistent with the measured value of the threshold voltage VTS of the gate structure GS.

As described with reference to FIG. 11A, when circuit characteristics are predicted based on measured values of physical characteristics, the number of wafers of which circuit characteristics may be predicted may be significantly smaller than the total number of manufactured wafers. That is, parameters for determining the matching between predicted circuit characteristics and measured circuit characteristics may be insufficient.

Referring to FIG. 11B, the slope SL_REF of the function generated by the regression analysis of the predicted value of the threshold voltage VTS and the index value Vt of the threshold voltage according to the comparative example may be close to “1.” That is, it is indicated that accuracy of the threshold voltage VTS predicted based on the measured values of the physical characteristics may be high.

In the example in FIG. 11B, the slope SL_COMP of the function generated by the regression analysis of the predicted value of the threshold voltage VTS and the measured value of the threshold voltage VTS may be significantly different from the slope SL_REF. This is because, since the parameter of the predicted value of the threshold voltage VTS according to the comparative example is insufficient, it may be difficult to normally derive a correlation between the predicted value of the threshold voltage VTS and the measured value. As in the example in FIG. 11B, as the correlation between the predicted value of the threshold voltage VTS and the measured value is not normally derived, it may be difficult to control the process based on the predicted value of the threshold voltage VTS.

Meanwhile, collecting measured values of the threshold voltage VTS or collecting the index value Vt of the threshold voltage may be performed after the process is completed, such that it may be difficult to perform rapid process control.

FIG. 11C is a graph illustrating a correlation between predicted circuit characteristics and measured circuit characteristics according to some example embodiments. The horizontal axis of the graph in FIG. 11C represents the measured value of the threshold voltage VTS, and the vertical axis represents the index value of the threshold voltage Vt and the measured value of the threshold voltage VTS. Arbitrary units (a.u.) may be used as units of the threshold voltage VTS and the index value Vt of the threshold voltage.

In some example embodiments, circuit characteristics of wafers for which physical characteristics are not measured may be predicted using predicted values based on virtual measurement. Accordingly, parameters for determining the matching between the predicted circuit characteristics and the measured circuit characteristics may be sufficient.

Referring to FIG. 11C, the slope SL_REF of a function generated as a result of performing a regression analysis of the measured value of the threshold voltage VTS and the index value Vt of the threshold voltage may be close to “1.” Also, the slope SL_VM of the function generated as a result of performing a regression analysis of the measured value and the predicted value of the threshold voltage VTS using sufficient parameters may be similar to the slope SL_REF.

Accordingly, by using the virtual measurement in the example embodiments, circuit characteristics may be predicted based on sufficient parameters, and the predicted values of the circuit characteristics may have high accuracy. Accordingly, quality abnormalities of the semiconductor device may be more accurately diagnosed using predicted values of circuit characteristics, and further, process control may be performed more swiftly and accurately.

FIG. 12 is a diagram illustrating a process control system according to an example embodiment.

Referring to FIG. 12, the characteristics management system 1000 may include a big data collection server 1100, a virtual measurement server 1200, and a characteristics prediction server 1300.

Each of the big data collection server 1100, the virtual measurement server 1200, and the characteristic prediction server 1300 may include a processor and a memory. The processor may control overall operation of the server, may access memory, and may execute instructions loaded into memory. The big data collection server 1100, the virtual measurement server 1200, and the characteristic prediction server 1300 may communicate with each other based on wired or wireless communication protocols. In some embodiments, each of the big data collection server 1100, the virtual measurement server 1200, and the characteristic prediction server 1300 may include a plurality of processors. In some embodiments, two or more of the big data collection server 1100, the virtual measurement server 1200, and the characteristic prediction server 1300 may be integrated into a single server.

The big data collection server 1100 may collect log data and measured values from a semiconductor fab FAB and may store the obtained log data and measured values. The log data may include process path information of wafers manufactured in a semiconductor fab FAB. Also, the measured values may include measured values of one or more physical characteristics of sample wafers selected from among the manufactured wafers. Identifiers may be assigned to wafers manufactured in the semiconductor fab FAB, and the log data and measured values may be managed in the big data collection server 1100 based on the identifiers of the wafers.

The virtual measurement server 1200 may obtain log data and measured values from the big data collection server 1100. The virtual measurement server 1200 may calculate moving average values of the measured values for each of the process paths based on the obtained measured values and the log data. Since the log data may be managed based on wafer identifiers, the log data and measured values used to calculate the moving average values may be identified among overall log data acquired from the big data collection server 1100.

The virtual measurement server 1200 may generate predicted values for physical characteristics of unmeasured target wafers based on the obtained log data. For example, the virtual measurement server 1200 may analyze a process path of each target wafer based on the log data, and may generate a predicted value based on moving average values of measured values for each process path.

The virtual measurement server 1200 may perform (e.g., may perform independently) virtual measurement of various types of physical characteristics on a wafer. For example, the virtual measurement server 1200 may perform virtual measurement on the first physical characteristic using log data and measured values of first sample wafers on which the first physical characteristic is measured among wafers manufactured in a semiconductor fab FAB. Also, the virtual measurement server 1200 may perform virtual measurement on the second physical characteristic using log data and measured values of the second sample wafers on which the second physical characteristic is measured among the wafers manufactured in the semiconductor fab FAB. A portion of the first sample wafers and the second sample wafers may overlap each other.

Meanwhile, a control signal based on predicted values of the virtual measurement server 1200 may be feedbacked from the virtual measurement server 1200 to the semiconductor fab FAB. The semiconductor fab FAB may adjust process conditions of a process device included in a certain process path and/or may repair a process device based on the control signal.

The characteristic prediction server 1300 may predict circuit characteristics based on measured values obtained from the big data collection server 1100 and predicted values obtained from the virtual measurement server 1200. The characteristic prediction server 1300 may derive regression analysis equations for physical characteristics and circuit characteristics by performing multiple regression analysis based on measured values of various physical characteristics and measured values of circuit characteristics.

The characteristic prediction server 1300 may predict the circuit characteristics of the semiconductor device by applying the derived regression analysis equation to the measured values obtained from the big data collection server 1100 and the predicted values obtained from the virtual measurement server 1200.

Meanwhile, a control signal based on a result of predicting circuit characteristics may be feedbacked from the characteristic prediction server 1300 to the semiconductor fab FAB. The semiconductor fab FAB may adjust process conditions of a process device included in a certain process path and/or may repair the process device based on the control signal.

FIG. 13 is a diagram illustrating the virtual measurement server 1200 in FIG. 12 in greater detail.

FIG. 13 is a block diagram illustrating a virtual measurement server 1200 configured to perform wafer inspection according to an example embodiment of the present disclosure. Referring to FIG. 13, a virtual measurement server 1200 may include at least one processor 1210 connected to a system bus, a working memory 1220, an input/output device 1230, and an auxiliary storage device 1240.

The virtual measurement server 1200 may be provided as a dedicated device for virtual measurement. For example, the virtual measurement server 1200 may include a program for virtual measurement. The processor 1210, the working memory 1220, the input/output device 1230, and the auxiliary storage device 1240 may be electrically connected to each other and may exchange data with each other through the system bus.

The processor 1210 may be implemented to execute at least one instruction. For example, the processor 1210 may be implemented to execute software (application programs, operating systems, device drivers) to be executed on the virtual measurement server 1200. The processor 1210 may execute an operating system loaded into the working memory 1220. The processor 1210 may execute various application programs to be driven based on an operating system. For example, the processor 1210 may be a central processing unit (CPU), a microprocessor, an application processor (AP), or any processing device similar thereto.

The working memory 1220 may be implemented to store at least one instruction. For example, an operating system or application programs may be loaded into the working memory 1220. When the virtual measurement server 1200 boots, the OS image stored in the auxiliary storage device 1240 may be loaded into the working memory 1220 according to a booting sequence. Overall input/output operations of the virtual measurement server 1200 may be supported by the operating system. Similarly, application programs selected by a user or to provide basic services may be loaded into the working memory 1220. In particular, a virtual metrology tool 1210 including instructions for performing virtual metrology on physical characteristics of a wafer may be loaded into the working memory 1220.

Also, the working memory 1220 may be implemented as a volatile memory such as dynamic random access memory (DRAM) or static random access memory (SRAM), or a nonvolatile memory such as a flash memory, phase change random access memory (PRAM), resistance random access memory (RRAM), Nano floating gate memory (NFGM), polymer random access memory (PoRAM), magnetic random access memory (MRAM), ferroelectric random access memory (FRAM), and/or the like.

The input/output device 1230 may obtain log data of manufactured wafers and measured values of sample wafers, and may output predicted values of target wafers generated by virtual measurement.

The auxiliary storage device 1240 may be provided as a storage medium of the virtual measurement server 1200. The auxiliary storage device 1240 may store application programs, OS images, and various data. The auxiliary storage device 1240 may be provided in the form of a mass storage device such as a memory card (MMC, eMMC, SD, or a micro SD), a hard disk drive (HDD), a solid state drive (SSD), or universal flash storage (UFS).

In some example embodiments, the virtual measurement server 1200 may generate predicted values of target wafers that have relatively high consistency with measured values of measured wafers, with the virtual measurement server 1200 generating the predicted values of target wafers based on the measured values of the measured wafers that have or travelled the same process path as that of the target wafers.

According to the aforementioned example embodiments, the characteristic prediction server 1300 may predict circuit characteristics of wafers which are not measured by using measured values and having relatively high matching with the measured values. Accordingly, circuit characteristics of wafers may be predicted accurately and swiftly.

Also, the process control system 1000 may provide relatively rapid feedback for semiconductor process control to a semiconductor fab based on a virtual measurement result and a circuit characteristic prediction result.

While some example embodiments have been illustrated and described above, it will be apparent to those skilled in the art that modifications and variations could be made without departing from the scope of the present disclosure as defined by the appended claims.

What is claimed is:

1. A virtual metrology method for a wafer, the virtual metrology method comprising:
collecting log data including process path information of wafers manufactured in a semiconductor process;
collecting measured values of sample wafers of which physical characteristics are measured in the semiconductor process, the sample wafers being a group of wafers selected from among the manufactured wafers;
classifying measured values of the sample wafers according to process paths based on the process path information;
calculating a moving average value of measured values classified for each process path; and
determining a moving average value corresponding to a process path of an unmeasured target wafer from among the manufactured wafers as a predicted value of physical characteristics of the target wafer.

2. The virtual metrology method of claim 1,
wherein the semiconductor process includes a plurality of unit processes performed in sequence in chambers of process devices, and
wherein the process path information indicates under which process conditions the manufactured wafers were processed in which chamber of which process device for each of the plurality of unit processes.

3. The virtual metrology method of claim 1,
wherein the semiconductor process includes a front-end-of-line (FEOL) process, a middle-of-line (MOL) process, and a back-end-of-line (BEOL) process, each of which includes a plurality of unit processes, each unit process performed in a chamber of a process device, and
wherein the process path information indicates under which process conditions processing is performed in which chamber of which process device in each of a plurality of unit processes included in a process in which the physical characteristics are measured among the FEOL process, the MOL process, and the BEOL process.

4. The virtual metrology method of claim 3,
wherein the physical characteristics are one of a depth of shallow trench isolation (STI) included in the wafer, a depth of a buried channel array transistor (BCAT) of gate structures, and a height of a fin structure of active regions, and
wherein the process path information indicates under which process conditions processing is performed in which chamber of which process device in each of the plurality of unit processes included in the FEOL process.

5. The virtual metrology method of claim 1, wherein the physical characteristics include a vertical profile of patterns on a wafer, measured by an optical critical dimension (OCD) metrology device.

6. The virtual metrology method of claim 1, wherein the physical characteristics include a horizontal profile of patterns on a wafer, measured by a scanning electron microscope (SEM).

7. The virtual metrology method of claim 1, wherein the calculating a moving average value of the classified measured values comprises:
determining whether measured values of sample wafers manufactured within a first period from a reference time point among the classified measured values are collected in a predetermined amount or more for each process path; and
calculating an average value of the collected measured values for each process path in the first period, when a predetermined amount or more of measured values are collected for overall process paths.

8. The virtual metrology method of claim 7, wherein the calculating a moving average value of the classified measured values further includes collecting more measured values by increasing the first period when the measured values for at least a portion of the process paths are collected in less than the predetermined amount.

9. The virtual metrology method of claim 7, wherein the reference time point is a time point at which the virtual metrology method is performed.

10. A method of predicting circuit characteristics of a target wafer, the method comprising:
collecting measured values of sample wafers among wafers manufactured in a semiconductor process and measuring one or more physical characteristics among a plurality of physical characteristics of the sample wafers;
classifying the collected measured values according to process paths of the sample wafers;
determining predicted values of one or more physical characteristics among the plurality of physical characteristics of the target wafer using a process path of the target wafer, the target wafer not among the sample wafers; and
predicting circuit characteristics of the target wafer using measured values of the sample wafers and predicted values of the target wafer.

11. The method of claim 10, further comprising:
generating a regression analysis equation for predicting the circuit characteristics based on the plurality of physical characteristics by performing multiple regression analysis of measured values of the plurality of physical characteristics of the wafer and measured values of the circuit characteristics.

12. The method of claim 11, wherein the generating a regression analysis equation includes determining a correlation coefficient with a measured value of the circuit characteristic for each of the plurality of physical characteristics.

13. The method of claim 11,
wherein the collecting of the measured values of sample wafers includes:
collecting measured values of first sample wafers of which a first physical characteristic among the plurality of physical characteristics is measured among the manufactured wafers; and
collecting measured values of second sample wafers of which a second physical characteristic among the plurality of physical characteristics are measured among the manufactured wafers, and
wherein a portion of the first sample wafers and a portion of the second sample wafers overlap.

14. The method of claim 13, wherein the determining of the predicted values of physical characteristics of the target wafer includes:
determining predicted values for the first physical characteristic of first target wafers excluding the first sample wafers among the manufactured wafers; and
determining predicted values for the second physical characteristic of second target wafers excluding the second sample wafers among the manufactured wafers.

15. The method of claim 11,
wherein the target wafer includes a plurality of memory devices, and
wherein the plurality of physical characteristics include:
a depth of shallow trench isolation (STI) included in the plurality of memory devices;
a depth of a buried channel array transistor (BCAT) of gate structures included in the plurality of memory devices; and
a height of a fin structure of active regions included in the plurality of memory devices.

16. The method of claim 15, wherein the circuit characteristics include a threshold voltage of the gate structures.

17. The method of claim 15,
wherein the semiconductor process includes a front-end-of-line (FEOL) process, a middle-of-line (MOL) process, and a back-end-of-line (BEOL) process, each of which includes a plurality of unit processes,
wherein the FEOL process includes a process of forming the STI, a process of forming the BCAT, and a process of forming the fin structure, and
wherein the classifying the collected measured values includes classifying measured values of a depth of the STI, measured values of a depth of the BCAT, and measured values of a height of the fin structure of the sample wafers according to process paths of the FEOL process.

18. A process control system, comprising:
a big data collection server configured to collect, from a semiconductor fab, log data including process path information of wafers manufactured in the semiconductor fab and measured values of physical characteristics of sample wafers selected from among the manufactured wafers;
a virtual measurement server configured to obtain the measured values of the sample wafers from the big data collection server, to classify the measured values according to process paths of the sample wafers, to generate predicted values of physical characteristics of unmeasured target wafers according to the classified measured values and process paths of target wafers, and to store the generated predicted values, the unmeasured target wafers being different from the sample wafers; and
a characteristic prediction server configured to obtain the measured values of the sample wafers from the big data collection server, to obtain the predicted values of the target wafers from the virtual measurement server, to predict circuit characteristics of the manufactured wafers using the measured values and predicted values, and to feedback a control signal to the semiconductor fab based on the predicted circuit characteristics.

19. The process control system of claim 18, wherein the virtual measurement server includes:
an input/output device configured to obtain the measured values of the sample wafers from the big data collection server;
a working memory into which instructions for virtual measurement are loaded;
a processor configured to classify the measured values according to process paths of the sample wafers by executing the instructions, and to generate predicted values of physical characteristics of the target wafers; and
an auxiliary storage device configured to store the generated predicted values.

20. The process control system of claim 18, wherein the virtual measurement server maps the measured values and the process paths based on identifiers of the sample wafers.
